(19) United States
(12) Patent Application Publication
(10) Pub. No.: US 2007/0243658 A1
(43) Pub. Date: Oct. 18, 2007

(54) Production method of crystalline organic semiconductor thin film, organic semiconductor thin film, electronic device, and thin film transistor

(76) Inventors: Katsura Hirai, Tokyo (JP); Reiko Obuchi, Yokohama-shi (JP)

Correspondence Address: CANTOR COLBURN, LLP, 55 GRIFFIN ROAD SOUTH, BLOOMFIELD, CT, 06002, US

(21) Appl. No.: 11/784,717

(22) Filed: Apr. 9, 2007

(30) Foreign Application Priority Data
Apr. 14, 2006 (JP) JP2006-111677

(51) Int. Cl. H01L 51/40

(52) U.S. Cl. 438/99

(57) ABSTRACT

A method of producing a crystalline organic semiconductor thin film including the steps of: (a) coating a solution of an organic semiconductor material in a solvent onto a substrate to form a liquid coating film; and (b) crystallizing the organic semiconductor material in the liquid coating film at an edge of the liquid coating film on the substrate so as to grow a crystalline of the organic semiconductor material.

### TECHNICAL FIELD

The present invention relates to a crystalline organic semiconductor thin film which is produced via a coating process employing a solution, and to an electronic device using the same and a thin film transistor.

### BACKGROUND

Along with the wide use of information terminals, need for flat panel displays as a computer display is being enhanced. Further, along with development of computerization, opportunities are increased in which information conventionally provided by paper media is further being provided via computerization. Consequently, as thin and light-weight mobile display media which are easily carried, need for electronic paper or digital paper is also being enhanced.

Heretofore, in the production of organic thin film transistors, an organic semiconductor layer (hereinafter also referred to as “an organic semiconductor thin film”) is formed employing a vacuum deposition method, or a wet process such as a spin coating method, or a casting method.

Incidentally, as a method to form a high quality organic semiconductor film with high mobility, a deposition method is representative, and various methods are employed depending on characteristics of employed materials. Of these, a method employing a wet process, in which a solution or liquid is applied onto a substrate via coating or ink jet printing, is characterized in that a thin film is easily prepared via deposition. A number of trials have been conducted to obtain an organic semiconductor film which exhibits carrier mobility equal to that of conventional silicon semiconductors, such as amorphous silicon.

Since carrier mobility in the organic semiconductor layer is determined based on molecular arrangement in the formed organic semiconductor material film, the molecular orientation is essential. In view of controlling the surface energy of a substrate onto which a semiconductor solution is applied, methods are reported in which molecular orientation is realized, for example, via employing an orientation film, or applying liquid crystalline materials onto an orientation treated surface. However, when only those processes are conducted, it has become difficult to increase the carrier mobility of the formed semiconductor material film and to enhance the performance of the thin film transistors.

On the other hand, with regard to crystal growth, employing a solution process, for example, a semiconductor film formed from a solution incorporating acenes, is described (for example, Patent Document 1), while thin film formation or crystal growth based on an ink-jet printing method is described (for example, Patent Document 2 or 3). Further, Patent Document 4 describes a semiconductor thin film formed from a solution. However, in those documents, no specific description is made of conformation of crystal growth. Further, according to any of the methods described in those documents, it is not possible to simply form desired crystalline thin film due to the reason in which in the course of growing crystal in a solution which is excessively saturated, bulk crystals tend to result due to the low crystal growth rate, whereby problems occur in which it is not possible to form a thin film suitable for thin film transistors due to low mobility of the resulting organic thin film transistors (TFT).

Differing from the above, Patent Document 5 discloses a method which forms an organic semiconductor film from a solution. The above document describes that it is possible to from a crystalline thin film, employing a method in which molecules are provided at the growth interface so that a thin film grows in the parallel direction to the substrate surface movement. After all, this document refers to a process employing a dipping process in which a substrate is immersed into an organic semiconductor material solution, and a thin film is formed via picking it up, whereby problems occur in which the production efficiency is low. Further, since an organic semiconductor thin film is formed at the meniscus between the solution and the substrate, a stationary meniscus is necessary, resulting in difficulties for production. Under common production environments, it is difficult to achieve a stationary meniscus, whereby problems occur in which it is not possible to realize desired characteristics due to an increase in defects.

(Patent Document 1) International Patent Publication Open to Public Inspection No. 03/16599

(Patent Document 2) Japanese Patent Publication Open to Public Inspection (hereinafter referred to as JP-A) No. 2003-192499

(Patent Document 3) JP-A No. 2005-28275

(Patent Document 4) JP-A No. 2000-307172

(Patent Document 5) U.S. Patent Publication Open to Public Inspection No. 2005/0199181

### SUMMARY

Accordingly, in view of the foregoing, the present invention was realized. An object of the present invention is to obtain, via simply forming a targeted crystalline thin film by continuously forming a coating film, a production method of a crystalline organic semiconductor thin film which results in excellent productivity and high carrier mobility, a crystalline organic semiconductor thin film using the same, an electronic device and an organic semiconductor thin film transistor using the aforesaid crystalline organic semiconductor thin film.

The present invention is realized via the following embodiments.

(1) An aspect of the present invention is a method of producing a crystalline organic semiconductor thin film comprising the steps of:

(a) coating a solution of an organic semiconductor material in a solvent onto a substrate to form a liquid coating film; and

(b) crystallizing the organic semiconductor material in the liquid coating film at an edge of the liquid coating film on the substrate so as to grow a crystalline of the organic semiconductor material.

(2) Another aspect of the present invention is a method of producing a crystalline organic semiconductor thin film, wherein the crystalline organic semiconductor thin film grows by moving a solid-liquid interface formed by a crystallized portion and a liquid portion of the coating film.

### (3) Another aspect of the present invention is a method of producing a crystalline organic semiconductor thin film,

wherein the crystallization step (b) is conducted by evaporation of the solvent in the coating film.

### (4) Another aspect of the present invention is a method of producing a crystalline organic semiconductor thin film,

wherein a moving rate of the solid-liquid interface is controlled so as to be 20 μm/sec or more in a direction parallel to a coating direction.

### (5) Another aspect of the present invention is a method of producing a crystalline organic semiconductor thin film, wherein the liquid coating film of the solution of the organic semiconductor material has a thickness of 500 μm or less.

### (6) Another aspect of the present invention is a method of producing a crystalline organic semiconductor thin film,

wherein the organic semiconductor material is a condensed polycyclic aromatic compound.

### (7) Another aspect of the present invention is a method of producing a crystalline organic semiconductor thin film,

wherein the organic semiconductor material is a condensed polycyclic aromatic compound represented by Formula (OSC1):

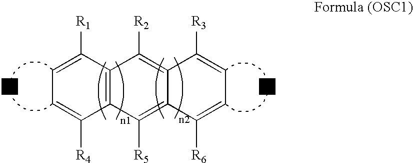

wherein R₁-R₆ each represent a hydrogen atom or a substituent; Z₁ and Z₂ each represent a group of atoms to form a substituted or unsubstituted aromatic hydrocarbon ring, or a substituted or unsubstituted aromatic heterocyclic ring; and n1 and n2 each represent an integer of 0-3.

### (8) Another aspect of the present invention is a method of producing a crystalline organic semiconductor thin film,

wherein the organic semiconductor material is a condensed polycyclic aromatic compound represented by Formula (OSC2):

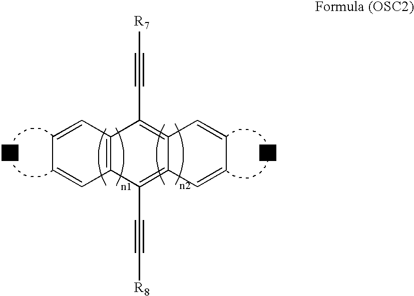

wherein R₇ and R₈ each represent a hydrogen atom or a substituent; Z₁ and Z₂ each represent a group of atoms to form a substituted or unsubstituted aromatic hydrocarbon ring, or a substituted or unsubstituted aromatic heterocyclic ring, and n1 and n2 each represent an integer of 0-3.

### (9) Another aspect of the present invention is a method of producing a crystalline organic semiconductor thin film,

wherein R₇ and R₈ in Formula (OSC2) each are represented by Formula (SG1):

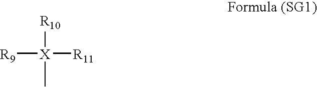

wherein R₉-R₁₁ each represent a substituent; and X represents Si, Ge, or Sn.

### (10) Another aspect of the present invention is an organic semiconductor thin film produced by the method of the present invention.

### (11) Another aspect of the present invention is an electronic device comprising the organic semiconductor thin film of the present invention.

### (12) Another aspect of the present invention is a thin film transistor comprising the organic semiconductor thin film of the present invention.

According to the present invention, it is possible to provide a crystalline organic semiconductor thin film (being an organic semiconductor thin layer) which results in excellent coatability and high carrier mobility, and the production method thereof, and organic thin film transistors and electronic devices using the same.

### BRIEF DESCRIPTION OF THE DRAWINGS

FIG. 1 is a view showing the state of crystal growth at the wet film edge of an organic semiconductor material coating film.

FIG. 2 is a sectional view showing some constitutional examples of a thin film transistor of the present invention.

FIG. 3 is a view showing an embodiment which forms a crystalline organic semiconductor thin film employing a die coater.

FIG. 4 is a view of another embodiment which forms a crystalline organic semiconductor thin film employing a die coater.

FIG. 5 is a view showing an embodiment employing a coating roller.

FIG. 6 is a view showing formation of a crystalline organic semiconductor thin film via dip coating.

FIG. 7 is a view showing an embodiment via an ink-jet printing method.

FIG. 8 is a view showing the growth direction of a solution coating interface and a crystalline thin film.

### DESCRIPTION OF PREFERRED EMBODIMENTS

Preferred embodiments which enable practice of the present invention will now be described; however, the present invention is not limited thereto.

In the present invention, in order to form a crystalline organic semiconductor thin film, an organic semiconductor solution coating is once formed on a substrate. Thereafter, crystals are allowed to grow at the edge of the formed solution coating, and while moving the above crystal growth interface, a crystalline thin film is formed. By initially conducting the coating, a highly productive production method is realized which is capable of forming, at the desired thickness, a crystalline thin film of organic semiconductor materials, which exhibits desired quality across the broad region of the substrate, namely high carrier mobility.

The solution coating method employed in the present invention may be carried out using, for example, conventional coating methods or ink-jet printing methods, either of which continuously form a the targeted coating on the substrate.

In the present invention, along with backward movement and relative migration of the wet film edge of a continuous organic semiconductor material coating film, semiconductor molecules undergo crystal growth. Namely, crystal growth is achieved at the backward movement rate (or the migration rate) which is the same rate as the crystal growth rate. It is assumed that the crystal growth direction is equivalent to the π stack direction of semiconductor molecules.

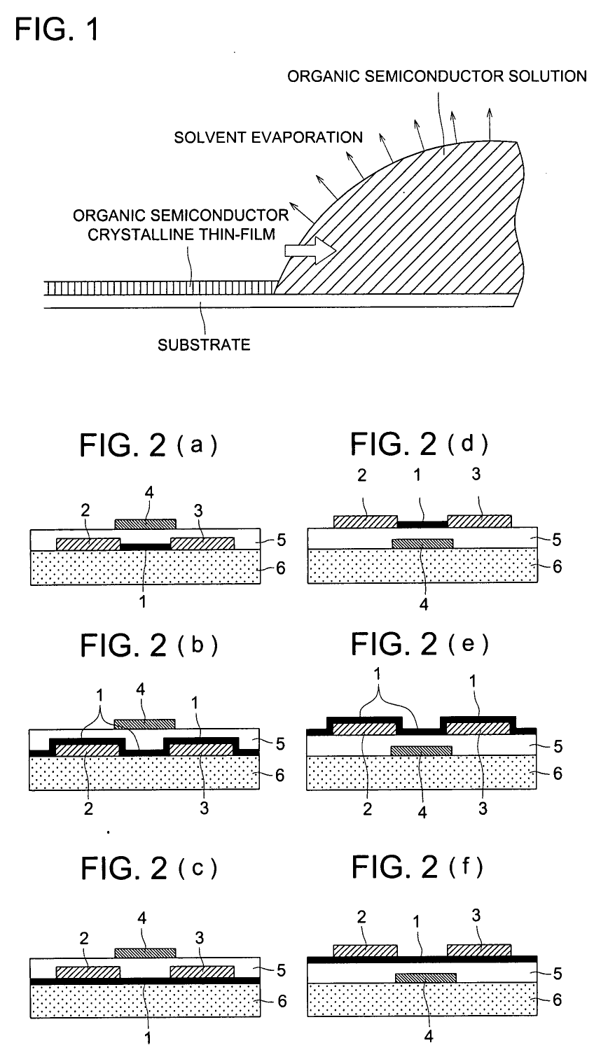

FIG. 1 is a view showing the state of crystal growth at the wet film edge of an organic semiconductor material coating film. Namely, at the edge of the solution coating, as the cross-section shows in FIG. 1, a solid/liquid interface is formed between the crystalline thin film and the solution coating. Via migration (backward movement) of the interface to the solution interior direction, a crystalline thin film is formed. In order to realize migration of the coating edge, it is possible to utilize a decrease in volume due to evaporation of solvents to reach equilibrium, shape changes of the solution coating due to the surface tension action, and dynamic force such as gravity.

Crystal growth rate is affected by the temperature of the substrate, types of solvent, and the surface energy of the substrate, but at the edge of the coating of an organic semiconductor material solution, crystallization progresses, while molecules are being oriented, via an equilibrium process along with the migration of the solid/liquid interface.

Further, in order to achieve efficient results in the process in which the crystallization interface sequentially migrates, it is preferable that after formation of the solution coating, crystal deposition is induced at the edge of the coating.

At the edge of the solution coating prior to appearance of any growth process of the above crystalline thin film, the air/liquid interface is relatively large and the film thickness decreases, resulting in an increase in the vaporization rate of solvents per volume of the semiconductor solution, and along with vaporization of solvents, the concentration of organic semiconductor materials increases, whereby crystals tend to be deposited. Being affected by so-called segregation or a phenomenon called coffee-staining, a concentration gradient results at the edge of the organic semiconductor material solution, whereby crystals are deposited. Crystals, generated as above, function as a crystal seed of the above crystalline thin layer, and effectively assist in the growth of the crystalline thin layer.

In order to achieve the above, it is preferable that the solution is allowed to stay at the edge for about 1-about 60 seconds to result in crystal deposition via segregation so that efficient growth of the crystalline thin layer is realized.

In the present invention, as mentioned above, it is preferable that a process is included in which a crystalline thin layer grows via migration of the crystal growth interface, namely simultaneously via migration of the edge of the solution wet coating. At the time, it is preferable to allow the above interface to migrate due to a decrease in the solution volume accompanying solvent evaporation. Also at the time, the migration rate of the edge of the solution coating (or also referred to a liquid coating film) parallel to a direction of coating on the substrate surface is preferably 1 μm/second, is more preferably 20 μm/second, but is further more preferably 100-1,000 μm/second.

Further, in the above solution coating, the thickness of the solution coating during migration of crystallizing interface is commonly 1-1,000 μm, is preferably 5-500 μm, but is further more preferably 1-100 μm. When the thickness falls below the lower limit, coatability of the solution coating is degraded, while when it exceeds the upper limit, the quality of the resulting crystalline thin layer is lowered.

Further, with regard to combinations of employed solvents or organic semiconductor materials, it is preferable to select combinations of solvents and semiconductor materials so that solubility of organic semiconductor materials employed to prepare the crystalline organic semiconductor thin film in the solvent is several percent, namely about 0.1-about 10% (at 25° C.), but preferably 1-10%.

Still further, in view of the thickness of the resulting crystalline organic semiconductor thin film and crystallization property, especially the size of the crystalline area, the concentration of organic semiconductor materials in the solution is commonly in the range of 0.001-10% by weight, is preferably in the range of 0.01-1% by weight, but is more preferably in the range of 0.05-0.5% by weight.

When the concentration of the organic semiconductor solution is excessively low, no crystal formation via segregation tends to occur. Further, even though crystals are formed, it is hard to prepare a single crystalline region. On the contrary, when it is excessively high, crystals are formed immediately, and a polycrystalline region, in which crystals are randomly oriented, tends to result, whereby it is difficult to prepare a large crystalline region having a single orientation plane.

Conditions such as temperature of a substrate to prepare a crystalline thin film, and the boiling point and vapor pressure of employed solvents are appropriately selected. The temperature is preferably room temperature-150° C.

It is preferable that the crystalline thin film prepared via the present invention has a single crystalline region. It is possible to confirm the single crystalline region with a polarization microscope. When observed via the polarization microscope employing cross-Nicol, the single crystalline region is confirmed as a region in which the resulting birefringence is in the uniform state, namely the region in which bright and dark changes observed during rotation of the sample result in a single change over the entire crystalline region.

In practice of the present invention, a plurality of these single crystalline regions is formed. The size of the single crystalline region is preferably in the range of about 25 μm²-25 mm², but is more preferably in the range of 100 μm²-25 mm². The entire region may be composed of the single crystalline region. However, the above size is appropriate to form semiconductor element channels.

In the formed thin-crystalline film, it is preferable that the crystal region, exhibiting a uniform birefringence state, has a size in which a source electrode and a drain electrode are arranged in which channels can be formed. Accordingly, in the present invention, the size of the above crystal region is in the range of several μ m to several thousand μ m in terms of length.

Further, it is preferable that the source electrode and the drain electrode are arranged so that one crystal region is present between them. Since crystal orientation/growth is carried out in the growth direction of the crystalline thin film, namely at the nearly right angles to the interface of the coating, it is preferable that, if possible, the channels between the source electrode and the drain electrode are arranged in the same direction as the growth direction of the above crystalline thin film.

The forming method of the crystalline organic semiconductor thin film according to the present invention can be applied to the thin film formation of various crystalline organic semiconductor materials, and conjugated compounds, such as the various condensed polycyclic aromatic compounds listed below, can be employed.

Examples of the condensed polycyclic aromatic compounds as an organic semiconductor martial include anthracene, tetracene, pentacene, hexacene, heptacene, chrysene, picene, fuluminene, pyrene, peropyrene, perylene, terylene, quoterylene, coronene, ovalene, circumanthracene, bisanthene, sesulene, heptasesulene, pyranthrene, violanthene, isoviolanthene, circobiphenyl, phthalocyanine, and porphyrin, as well as derivatives thereof.

Examples of other conjugated compounds may include polythiophene and oligomers thereof, polypyrrole and oligomers thereof, polyaniline, polyphenylene and oligomers thereof, polyphenylene vinylene and oligomers thereof, polythienylene vinylene and oligomers thereof, polyacetylene, polydiacetylene, tetrathiafluvalene compounds, quinone compounds, cyano compounds such as tetracyanoquinodimethane, and fullerene, as well as derivatives and mixtures thereof.

Further, among polythiophene and oligomers thereof, specifically employed may be oligomers in the structure of thiophene hexamers, such as α-sexithiophene α,ω-dihexyl-α-sexithiophene, α,ω-dihexyl-α-quinquethiophene, or α,ω-bis(3-butoxypropyl)-α-sexithiophene.

Further listed are metal phthalocyanines such as copper phthalocyanine, or fluorine-substituted copper phthalocyanine described in JP-A No. 11-251601; condensed ring tetracarboxylic acid dimides such as naphthalenetetracarboxylic acid dimides including naphthalene-1,4,5,8-tertacarboxylic acid diimide, N,N′-bis(4-trifluoromethylbenxyl)naphthalene-1,4,5,8-tetracarboxylic acid diimide, N,N′-bis(1H,1H-perfluorooctyl), N,N′-bis(1H,1H-perfluorobutyl), N,N′-dioctylnaphthalene-1,4,5,8-tetracarboxylic acid diimide derivatives, or naphthalene-2,3,6,7-tetracarboxylic acid diimide and anthracenetetracarboxylic acid diimides including anthracene-2,3,6,7-tetracarboxylic acid diimide; fullerenes such as C60, C70, C76, C78, or C84; carbon nano-tubes such as SWNT; and dyes such as merocyanines or hemicyanines.

Of these π conjugated materials, preferred is a type selected from the group consisting of condensed polycyclic aromatic compounds such as pentacene, fullerenes, condensed ring tetracarboxylic acid diimides, and metal phthalocyanines.

Further, employed as other organic semiconductor materials may be organic complexes such as tetrafluvalene (TTF)-tetracyanoquinodimethane (TCNQ) complexes, bisethylenetetrathiafluvalene (BEDTTTF)-perchloric acid complexes, BEDTTTF-iodine complexes, or TCNQ-iodine complexes. Further employed may be σ conjugated polymers such as polysilane or polygerman, and organic and inorganic mixtures described in JP-A No. 2000-260999.

Further, of the above polythiophenes and oligomers thereof preferred are the thiophene oligomers represented by following Formula (1).

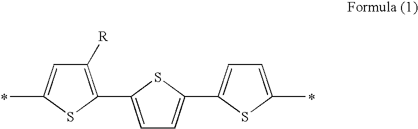

wherein R represents a substituent.

### Thiophene Oligomers Represented by Formula (1):

The thiophene oligomers represented by above Formula (1) will now be described.

Examples of the substituents represented by R in Formula (1) include an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group), a cycloalkyl group (for example, a cyclopentyl group and a cyclohexyl group), an alkenyl group (for example, a vinyl group and an allyl group), an alkynyl group (for example, an ethynyl group and a propagyl group), an aryl group (for example, a phenyl group, a p-chlorophenyl group, a mesityl group, a tolyl group, a xylyl group, a naphthyl group, an anthoryl group, an azulenyl group, an acenaphthenyl group, a fluorenyl group, a phenatolyl group, an indenyl group, a pyrenyl group, and a biphenyl group), an aromatic heterocyclyl group (for example, a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, and a phthalazyl group), a heterocyclyl group (for example, a pyrrolidyl group, an imidazolydyl group, a morpholyl group, and an oxazolydyl group), an alkoxy group for example, a methoxy group, an ethoxy group, a propyloxy group, a pentyloxy group, a hexyloxy group, an octyloxy group, and a dodecyloxy group), a cycloalkoxy group (for example, a cyclopentyloxy group and a cyclohexyloxy group), an aryloxy group (for example, a phenoxy group and a naphthyloxy group), an alkylthio group (for example, a methylthio group, an ethylthio group, a propylthio group, a pentylthio group, a hexylthio group, an octylthio group, and a dodecylthio group), a cycloalkylthio group (for example, a cyclopentylthio group and a cyclohexylthio group), an arylthio group (for example, a phenylthio group and a naphthylthio group), an alkoxycarbonyl group (for example, a methyloxycarbonyl group, an ethyloxycarbonyl group, a butyloxycarbonyl group, an octyloxycarbonyl group, and a dodecyloxycarbonyl group), an aryloxycarbonyl group (for example, a phenyloxycarbonyl group and a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group), an acyloxy group (for example, an acetyloxy group, an ethylcarbonyloxy group, a butylcarbonyloxy group, an octylcarbonyloxy group, a dodecylcarbonyloxy group, and a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group), a sulfinyl group (for example, a methylsulfonyl group, an ethylsulfonyl group, a butylsulfonyl group, a cyclohexylsulfinyl group, a 2-ethylhexylsulfinyl group, a dodecylsulfinyl group, a phenylsulfonyl group, a naphthylsulfinyl group, and a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, and a dodecylsulfonyl group), an arylsulfonyl group (for example, a phenylsulfonyl group, a naphthylsulfonyl group, and a 2-pyridylsulfonyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, and a 2-pyridylamino group), an halogen atom (for example, a fluorine atom, a chlorine atom, and a bromine atom), a fluorinated hydrocarbon group (for example, a fluoromethyl group, a trifluoromethyl group, a pentafluoroethyl group), a cyano group, a silyl group (for example, a trimethylsilyl group, a triisopropylsilyl group, a triphenylsilyl group, and a phenyldiethylsilyl group).

These substituents may further be substituted with the above substituents, and a plurality of the above substituents may join to form a ring.

Of these, the preferred substituent is an alkyl group, the more preferred one is an alkyl group having 2-20 carbon atoms, but the most preferred one is an alkyl group having 6-12 carbon atoms.

### Terminal Group of Thiophene Oligomers:

The terminal group of thiophene oligomers employed in the present inventions will now be described.

It is preferable that the terminal group of the thiophene oligomers employed in the present invention has no thienyl group. Listed as preferred groups in the above terminal group are an aryl group (for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenlyl group), an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group), a halogen atom (for example, a fluorine atom, a chlorine atom, and a bromine atom).

### Characteristics of Steric Structure of Repeating Unit of Thiophene Oligomer:

It is preferable that thiophene oligomers employed in the present invention have no head-to-head structure. In addition, it is more preferable that a head-to-tail structure or a tail-to-tail structure is incorporated.

With regard to the head-to-head structure, the head-to-tail structure and the tail-to-tail structure according to the present invention, reference can be made, for example, on pages 27-32 of “π Denshi Kei Yuki Kotai (π Electron Based Organic Solids” (edited by the Chemical Society of Japan, published by Gakkai Shuppan Center, 1998) and to Adv. Mater. 1998. 10, No. 2, pages 93-116. Each of the structural characteristics will now be specifically described.

R is as defined for R in Formula (1).

Head-to-Head Structure

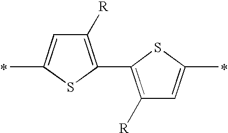

Head-to-Tail Structure

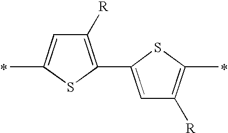

Tail-to-Tail Structure

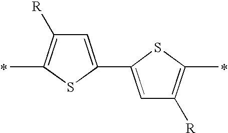

Specific examples of the thiophene oligomers employed in the present invention are listed below; however, the present invention is not limited thereto.

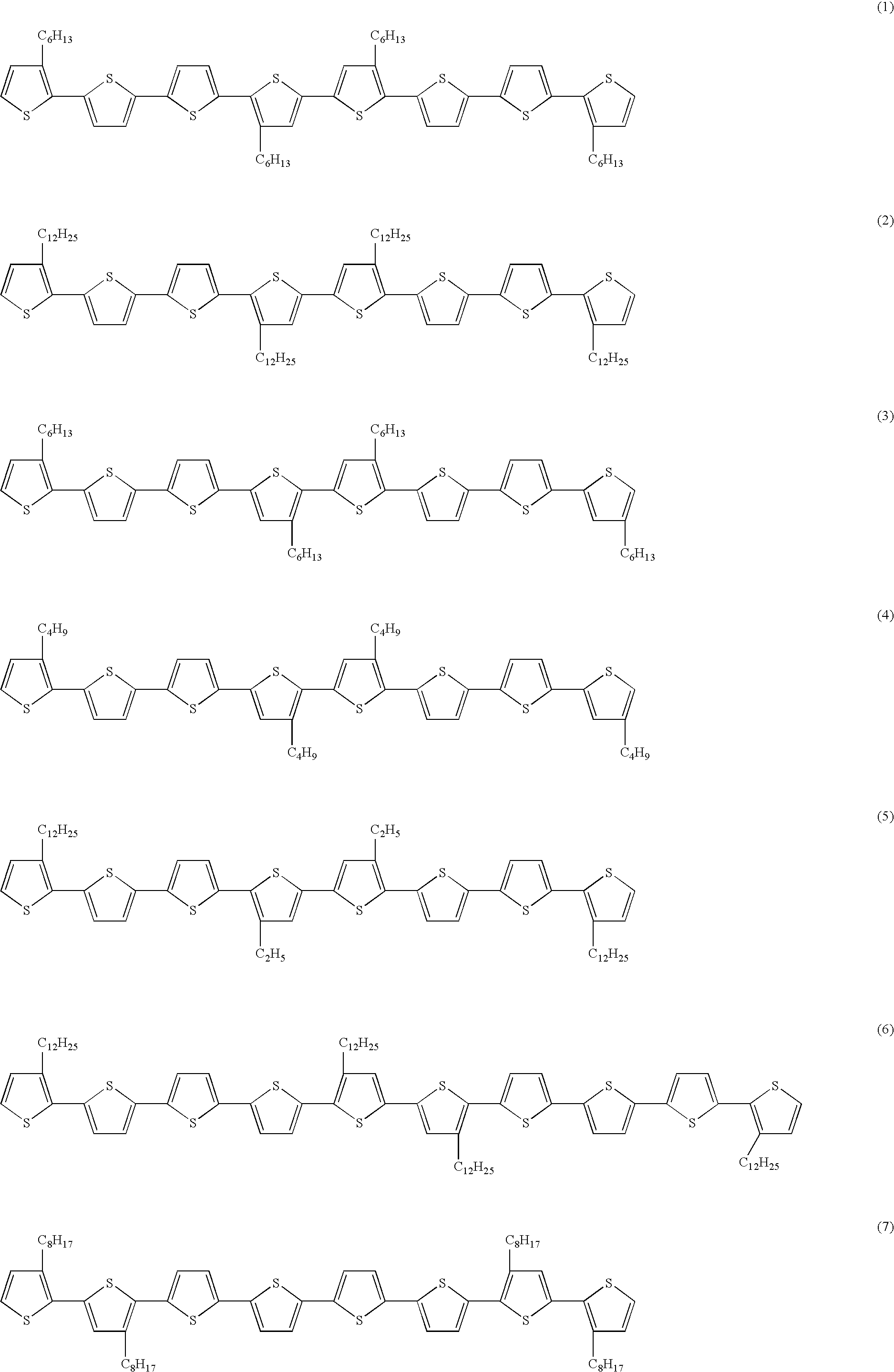

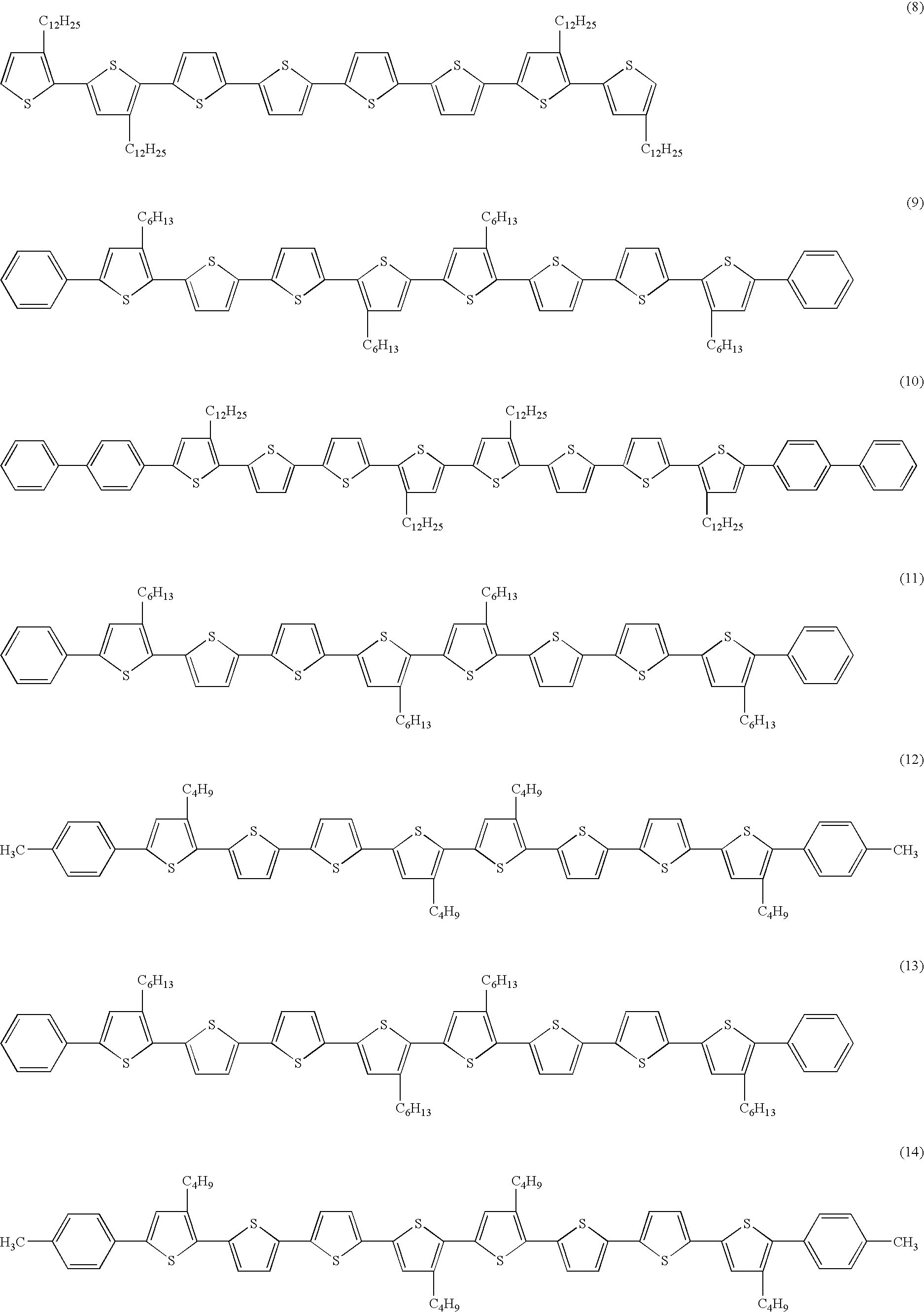

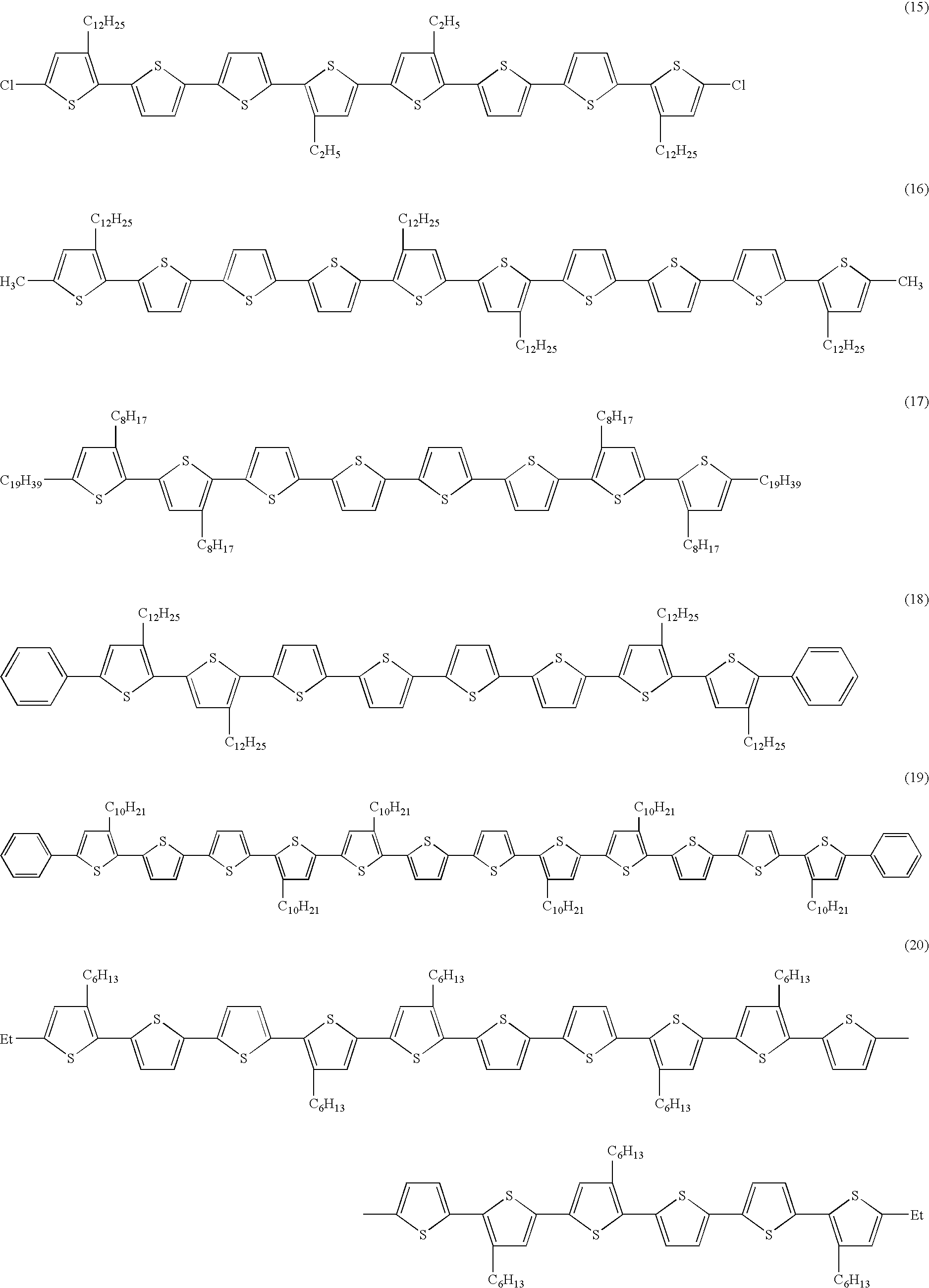

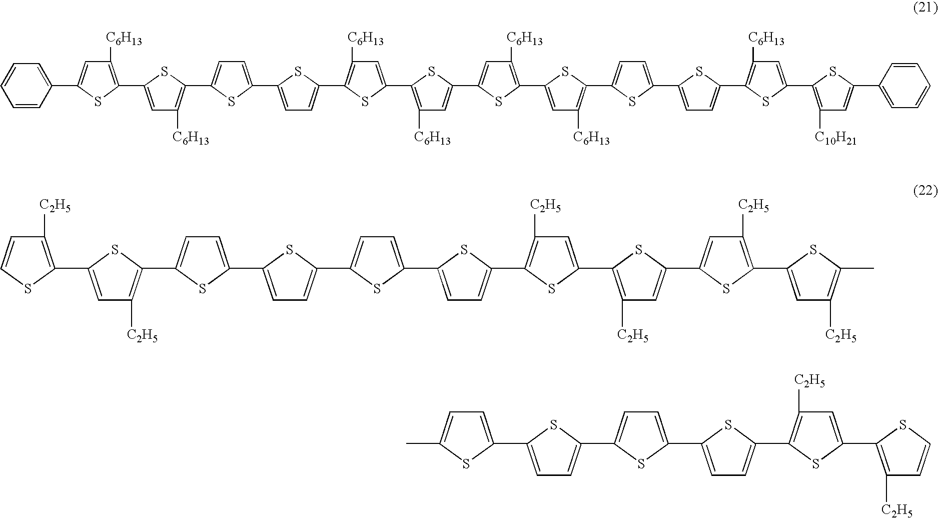

The production method of these thiophene oligomers is described in Japanese Patent Application No. 2004-172317 (applied on Jun. 10, 2004) via the inventors of the present invention.

Further, in the present invention, particularly preferred as an organic semiconductor material are the compounds represented by following Formula (OSC1).

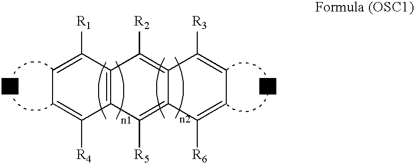

wherein R₁-R₆ each represent a hydrogen atom or a substituent, Z₁ and Z₂ each represent a group of atoms to form a substituted or unsubstituted aromatic hydrocarbon ring, or a substituted or unsubstituted aromatic heterocyclic ring, and n1 and n2 each represent an integer of 0-3.

In Formula (OSC1), the substituents represented by each of R₁-R₆ include an alkyl group (for example, a methyl group, an ethyl group, a propyl group, an isopropyl group, a tert-butyl group, a pentyl group, a tert-pentyl group, a hexyl group, an octyl group, a tert-octyl group, a dodecyl group, a tridecyl group, a tetradecyl group, and a pentadecyl group), a cycloalkyl group (for example, a cyclopentyl group and a cyclohexyl group), an alkenyl group (for example, a vinyl group, an allyl group, a 1-propenyl group, a 2-butenyl group, a 1,3-butadienyl group, a 2-pentenyl group, and an isopropenyl group), an alkynyl group (for example, an ethynyl group and a propagyl group), an aromatic hydrocarbon group (an aromatic hydrocarbon group, also called an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenyl group), an aromatic heterocyclyl group (also called a heteroaryl group, for example, a pyridyl group, a pyrimidyl group, a furyl group, a pyrrolyl group, an imidazolyl group, a benzimidazolyl group, a pyrazolyl group, a pyrazinyl group, a triazolyl group (for example, a 1,2,4-triazole-1-yl group and a 1,2,3-triazole-1-yl group), an oxazolyl group, a benzoxazolyl group, a thiazolyl group, an isooxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, diazacarbazolyl group (which shows one in which one of carbon atoms constituting the carbon ring of the above carbolinyl group is replaced with a nitrogen atom), a quinoxalynyl group, a pyridazinyl group, a triazinyl group, a quinazolynyl group, and a phthalazinyl group), a heterocyclyl group (for example, a pyrrolidyl group, an imidazolydyl group, a morpholyl group, and an oxazolydyl group), an alkoxy group for example, a methoxy group, an ethoxy group, a propyloxy group, a pentyloxy group, a hexyloxy group, an octyloxy group, and a dodecyloxy group), a cycloalkoxy group (for example, a cyclopentyloxy group and a cyclohexyloxy group), an aryloxy group (for example, a phenoxy group and a naphthyloxy group), an alkylthio group (for example, a methylthio group, an ethylthio group, a propylthio group, a pentylthio group, a hexylthio group, an octylthio group, and a dodecylthio group), a cycloalkylthio group (for example, a cyclopentylthio group and a cyclohexylthio group), an arylthio group (for example, a phenylthio group and a naphthylthio group), an alkoxycarbonyl group (for example, a methyloxycarbonyl group, an ethyloxycarbonyl group, a butyloxycarbonyl group, an octyloxycarbonyl group, and a dodecyloxycarbonyl group), an aryloxycarbonyl group (for example, a phenyloxycarbonyl group and a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group), an acyloxy group (for example, an acetyloxy group, an ethylcarbonyloxy group, a butylcarbonyloxy group, an octylcarbonyloxy group, a dodecylcarbonyloxy group, and a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, and a dodecylsulfonyl group), an arylsulfonyl group (for example, a phenylsulfonyl group, a naphthylsulfonyl group, and a 2-pyridylsulfonyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, and a 2-pyridylamino group), an halogen atom (for example, a fluorine atom, a chlorine atom, and a bromine atom), a fluorinated hydrocarbon group (for example, a fluoromethyl group, a trifluoromethyl group, and a pentafluoroethyl group), a cyano group, a nitro group, a hydroxyl group, a mercapto group, a silyl group (for example, a trimethylsilyl group, a triisopropylsilyl group, a triphenylsilyl group, and a phenyldiethylsilyl group).

These substituents may further be substituted with the above substituents, and a plurality of the above substituents may join to form a ring.

In Formula (OSC1), the aromatic hydrocarbon group or aromatic heterocyclyl group represented by Z₁ or Z₂ each is defined as the aromatic hydrocarbon group and the aromatic heterocyclyl group described as the substituent represented by each of above R₁-R₆.

Further preferred are the compounds represented by following Formula (OSC2).

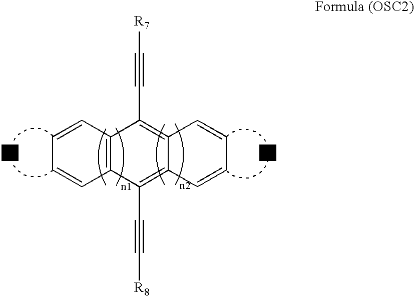

wherein R₇ and R₈ each represent a hydrogen atom or a substituent, Z₁ and Z₂ each represent a group of atoms to form a substituted or unsubstituted aromatic hydrocarbon ring, or a substituted or unsubstituted aromatic heterocyclyl ring, and n1 and n2 each represent an integer of 0-3.

In Formula (OSC2), the substituent represented by R₇ or R₈ each is defined as the substituent described as the substituent represented by each of above R₁-R₆. Further, the aromatic hydrocarbon group or aromatic heterocyclyl group represented by Z₁ or Z₂ each is defined as the aromatic hydrocarbon group and the aromatic heterocyclyl group described as the substituent represented by each of above R₁-R₆.

In above Formula (OSC2), it is preferable that substituents R₇ and R₈ are represented by Formula (SG1).

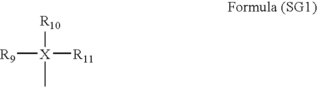

wherein R₉-R₁₁ each represent a substituent, and X represent silicon (Si), germanium (Ge), or tin (Sn).

In above Formula (SG1), the substituents represented by R₉-R₁₁ are each as defined for the substituents represented by R₁-R₆ in the above Formula (OSC1).

Specific examples of the compounds represented by above Formula (OSC2) are listed below; however, the present invention is not limited thereto.

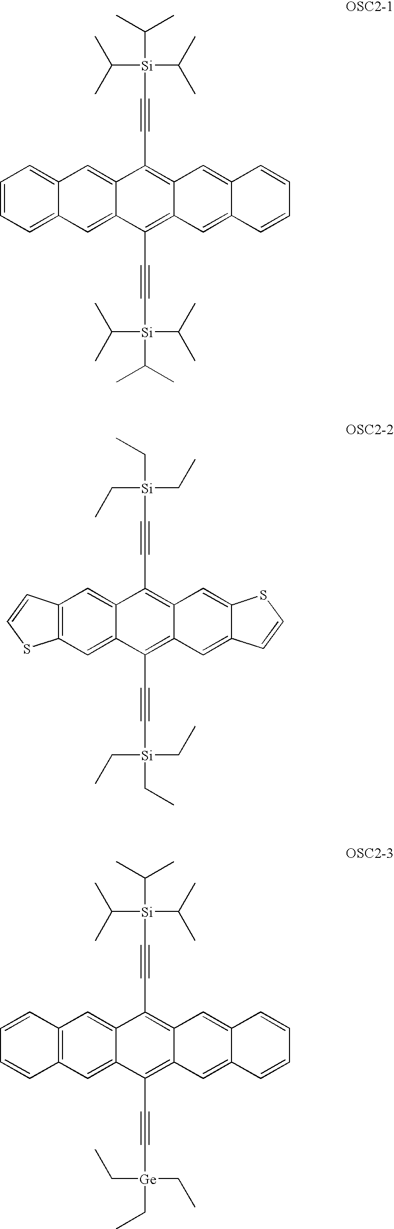

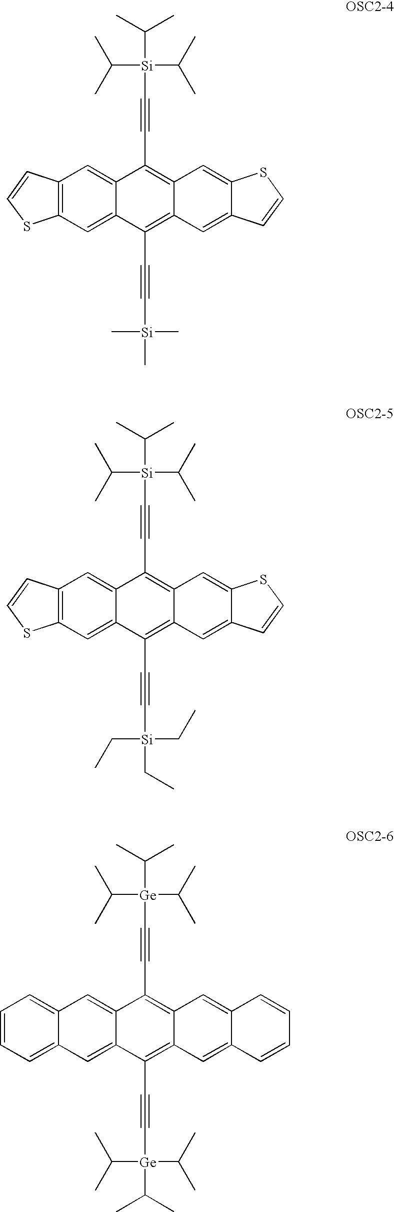

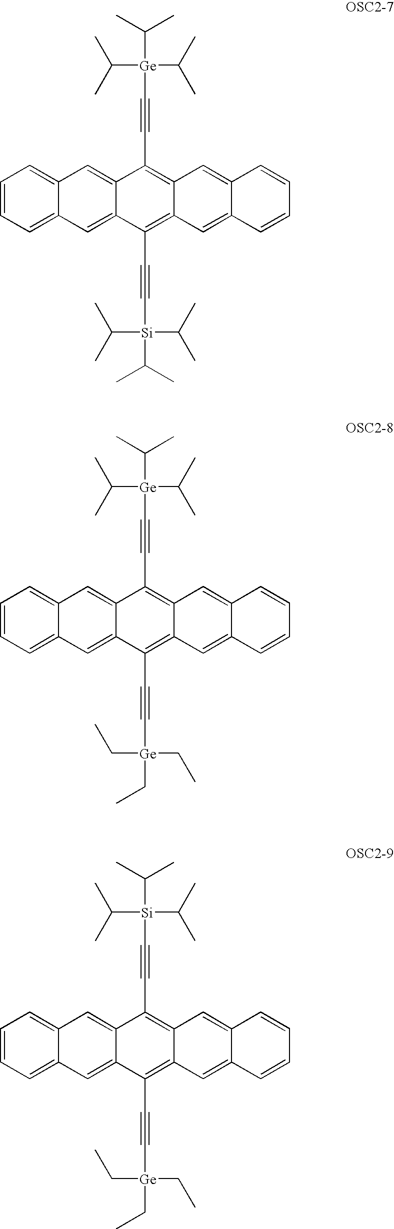

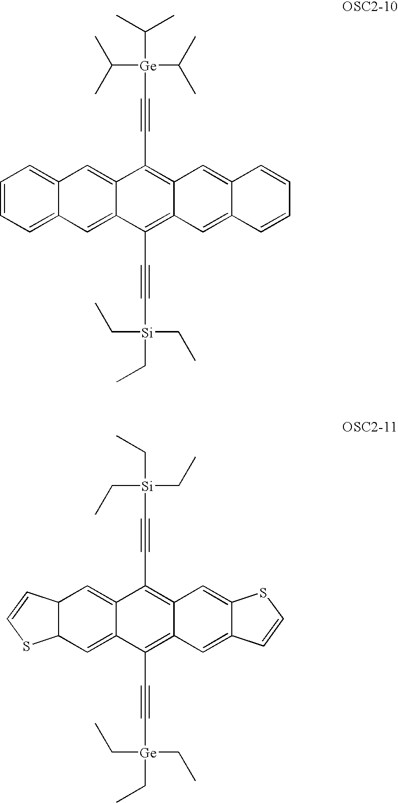

Further, in the present invention, incorporated may be materials such as acrylic acid or acetamide having a functional group such as a dimethylamino group, a cyano group, a carboxyl group, or a nitro group, materials such as tetracyanoethylene or tetracyanoquinodimethane and derivatives thereof which function as an acceptor which accepts electrons, materials having a functional group such as an amino group, a triphenyl group, an alkyl group, a hydroxyl group, an alkoxy group, or a phenyl group, substituted amines such as phenylenediamine, anthracene, benzanthracene, and substituted anthracenes, materials such as pyrene and substituted pyrene, carbazole and derivatives thereof, or tetrathiafulvalene and derivatives thereof which function as a donor which is a donor of electrons, whereby a so-called doping treatment is carried out.

Doping, as described above, refers to introduction of electron accepting molecules (acceptors) or electron donating molecules (donors) into a thin film as a dopant. Accordingly, a thin film which has undergone doping is one which incorporates the above condensed polycyclic aromatic compounds and dopants. Employed as dopants in the present invention may be those commonly known in the art.

In the present invention, formation of these organic semiconductor layers can be carried out employing coating methods such as spin coating, dip coating, a bar coating method, a die coating method, a spray coating method, and the LB method, as well as coating methods such as screen printing, ink-jet printing, or blade coating which employ a solution.

Of these, in terms of productivity, preferred are the spin coating method, the blade coating method, the dip coating method, the roller coating method, the bar coating method, and the die coating method, all of which can simply and precisely form a thin film employing a semiconductor solution.

Further, when these thin crystalline organic semiconductor films are produced employing the method of coating the organic semiconductor solution, it is possible to employ any appropriate solvent which constitutes the organic semiconductor solution. Appropriate solvents are selected from organic solvents such as those based on: hydrocarbons, alcohols, ethers, esters, ketones, or alcohol ethers, which exhibit appropriate vapor pressure and boiling point covering a wide range upon considering organic semiconductor compounds which are employed to prepare the organic semiconductor thin film.

Solvents which have a boiling point in the range of 60-150° C. at normal pressure are preferred, since such solvents exhibit an appropriate evaporation rate at the above crystal interface or at the edge of the liquid coating composition. For example, appropriately employed may be chain ether based solvents such as diethyl ether or diisopropyl ether, cyclic ether based solvents such as tetrahydrofuran or dioxane, ketone based solvents such as acetone, methyl ethyl ketone, or cyclohexane, aromatic hydrocarbon solvents such as xylene or toluene, aromatic solvents such as o-dichlorobenzene, nitrobenzene, or m-cresol, aliphatic hydrocarbon solvents such as hexane, cyclohexane, or tridecane, halogenated alkyl based solvents such as chloroform or 1,2-dichloroethane, N-methylpyrrolidone, and carbon disulfide. Of these, listed as preferable solvents are, for example, toluene and xylene.

The above restriction is eliminated by employing a coating apparatus or by reducing the ambience pressure during crystallization. However, the apparatus becomes serious.

The thickness of the crystalline organic semiconductor thin film (layer) formed via the production method of the present invention is not particularly limited. The characteristics of the resulting transistors significantly depend on the thickness of the organic semiconductor layer. The thickness is commonly at most 1 μm, but is most preferably 10-300 nm, though it depends on the type of solvent.

### (Surface Energy of Substrate and Contact Angle)

In view of coatability of solutions and crystal quality, the surface energy of the substrate on which the crystalline thin film is formed, for example, of the gate insulation film of a thin film transistor, is preferably 3.0×10⁻²-8.0×10⁻² N/m, but is more preferably 4.0×10⁻²-6.5×10⁻² N/m. Further, the water contact angle is preferably 20-90°, but is more preferably 30-75°.

In the thin film transistor element of the present invention, a source electrode or a drain electrode is formed via the above electroless plating method. However, neither the source electrode nor the drain electrode may be an electrode which is formed via the electroless plating, being the same as the gate electrode. In such a case, the electrode is formed via common methods known in the art, employing the electrode materials known in the art. Electrode materials are not particularly limited as long as they are electrically conductive. Employed materials include platinum, gold, silver, nickel, chromium, copper, iron, tin, antimony lead, tantalum, indium, palladium, tellurium, rhenium, iridium, aluminum, ruthenium, germanium, molybdenum, tungsten, tin-antimony oxide, indium-tin oxide (ITO), fluorine-doped zinc oxide, zinc, carbon, graphite, glassy carbon, silver paste and carbon paste, lithium, beryllium, sodium, magnesium, potassium, calcium, scandium, titanium, manganese, zirconium, gallium, niobium, sodium, sodium-potassium alloy, magnesium, lithium aluminum, magnesium/copper mixtures, magnesium/silver mixtures, magnesium/aluminum mixtures, magnesium/indium mixtures, aluminum/aluminum oxide mixtures, and lithium/aluminum mixtures. Alternatively, preferably employed are conductive polymers such as conductive polyaniline, conductive polypyrrole, or conductive polythiophene (such as a complex of polyethylene dixoythiophene and polystyrenesulfonic acid).

Of those listed above, preferred as a material to form the source electrode or the drain electrode are ones which exhibit low electrical resistance in the contact plane with the semiconductor layer. In the case of p type semiconductors, particularly preferred are platinum, gold, silver, ITO, conductive polymers, and carbon.

When materials are employed to form the source electrode or the drain electrode, it is preferable that the electrode is formed employing fluidic electrode materials such as a solution, a paste, an ink, or a dispersion which incorporates the above conductive materials. Of those, particularly preferred are fluidic electrode materials incorporating conductive polymers or minute metal particles of platinum, gold or copper. Further, as solvents and dispersion media, in order to protect organic semiconductors from damage, solvents or dispersion media are preferred which incorporate water in an amount of at least 60%, but preferably at least 90%.

For example, employed as fluidic electrode materials incorporating minute metal particles may be conductive pastes known in the art. Of these, preferred are materials which are prepared in such a manner that minute metal particles at a particle diameter of 1-50 nm, but preferably 1-10 nm, are dispersed into a dispersion medium such as water or any appropriate solvent, employing, if required, dispersion stabilizers.

Usable materials for minute metal particles include platinum, gold, silver, nickel, chromium, copper, iron, tin, antimony, lead, tantalum, indium, palladium, tellurium, rhenium, iridium, aluminum, ruthenium, germanium, molybdenum, tungsten, and zinc.

Production methods of the above minute metal particle dispersion include physical production methods such as an in-gas evaporation method, a sputtering method, or a metal vapor synthesis method, and chemical production methods such as a colloid method or a coprecipitation method in which minute metal particles are prepared via reducing metal ions in the liquid phase. Minute metal dispersions are preferred which are prepared via the colloid methods described in JP-A Nos. 11-76800, 11-80647, 11-319538, and 2000-239853, and the in-gas evaporation methods described in JP-A Nos. 2001-254185, 2001-53028, 2001-35255, 2000-124157, and 2000-123634. The electrode is formed employing any of the minute metal particle dispersions. After removing solvents via drying, heating is carried out in the temperature range of 100-300° C. but preferably 150-200° C. to result in the specified shape, whereby minute metal particles undergo heat fusion and an electrode pattern of the targeted shape is formed.

Electrode forming methods include one in which an electrode is formed in such a manner that a thin conductive film is prepared employing a method such as deposition or sputtering while employing the above materials as a raw material and the photolithographic method and the lift-off method, known in the art, is applied to the resulting film, and another method in which a resist is formed on a metal foil such as aluminum or copper via heat transfer or ink-jet printing, followed by etching. Further, patterning may be carried out via direct application of an ink-jet printing method employing a conductive polymer solution or dispersion, or a dispersion incorporating minute metal particles, or formation may be carried out from a coating employing lithography or laser ablation. Still further, it is possible to employ a method in which patterning is carried out via printing methods such as letterpress, intaglio, lithographic, or screen printing, employing a conductive ink or paste incorporating conductive polymers or minute metal particles.

It is preferable that the source electrode and the drain electrode are formed particularly employing the photolithographic method. In this case, a photoreactive resin solution is applied onto the entire area of the layer in contact with the organic semiconductor protective layer, and a photoreactive resin layer is formed. It is possible to apply photoreactive resins known in the art to the photoreactive layer. After pattern exposure, the photoreactive resin layer is developed to achieve patterning, whereby an electrode is formed. When a minute metal particle dispersion is employed as a material for the source electrode and the drain electrode, heat fusion may be conducted, if desired.

It is possible to employ various insulation films as a gate insulation layer of the organic thin film transistor element. Of these, an inorganic oxide film at a relative high dielectric constant is particularly preferred. Inorganic oxides include silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium isthmus titanate, strontium bismuth tantalate, bismuth tantalate niobate, and yttrium trioxide. Of these, preferred are silicon oxide, aluminum oxide, tantalum oxide, and titanium oxide. It is possible to employ appropriately inorganic nitrides such as silicon nitride or aluminum nitride.

Methods to form the above film include dry processes such as a vacuum deposition method, a molecular beam epitaxial deposition method, an ion cluster beam method, a low energy ion beam method, an ion plating method, a CVD method, a sputtering method, or an atmospheric pressure plasma method, as well as wet processes such as methods employing coating such as a spray coating method, a spin coating method, a blade coating method, a dip coating method, a casting method, or a roller coating method, a bar coating method, or a die coating method, and methods employing patterning such as printing or ink-jet printing. It is possible to employ any of these method depending materials.

In the wet processes, employed may be a method in which a liquid coating composition, which is prepared by dispersing minute inorganic oxide particles into any appropriate organic solvent or water employing, if necessary, dispersing aids such as surface active agents, is coated and subsequently dried, or a so-called sol-gel method in which a solution of oxide precursors such as alkoxides is coated and subsequently dried.

Of these, preferred is the atmospheric pressure plasma method described above. Formation of the insulation film via the atmospheric pressure plasma method is described, for example, in JP-A No. 2003-179234.

It is also preferable that the gate insulation film is composed of either an anodized film or the above anodized film and an insulation film. It is preferable that the anodized film undergoes a sealing treatment. The anodized film is formed in such a manner that anodizable metals undergo anodic oxidation via methods known in the art.

Listed as an anodizable metal may be aluminum or tantalum. Anodic treatment methods are not particularly limited, and methods known in the art are usable. By carrying out the anodic treatment, an oxidized film is formed. Electrolytes employed for the anodic treatment are not particularly limited as long as they can form a porous oxide film. Generally employed are sulfuric acid, phosphoric acid, oxalic acid, chromic acid, boric acid, sulfamic acid, benzenesulfonic acid, or mixed acids composed of at least above two acids, or salts thereof. Anodic treatment conditions are not completely specified since they vary depending on the used electrolyte. Generally, appropriate ranges are as follows. The concentration of the electrolyte is 1-80% by weight, the temperature of the electrolyte is 5-70° C., the current density is 0.5-60 A/dm², voltage is 1-100 V, and the electrolysis time is 10 seconds-5 minutes. A preferable anodic treatment employs a method in which an aqueous sulfuric acid, phosphoric acid, or boric solution is employed as the electrolyte and the treatment is carried out employing direct current, however alternating current may also be employed. The concentration of the acids is preferably 5-45% by weight. It is preferable to carry out electrolysis at an electrolyte temperature of 20-50° C., a current density of 0.5-20 A/dm², and a period of 20-250 seconds.

Further employed as the organic compound film may be polyimide, polyamide, polyester, polyacrylate, photo-radical polymerization based or photo-cationic polymerization based photocuring resins, or copolymers incorporating acrylonitrile components, polyvinyl phenol, polyvinyl alcohol, novolak resins, and cyanoethyl pullulan.

The above wet process is preferred as the method to form the organic compound film.

An inorganic oxide film and an organic oxide film may be simultaneously employed via superimposition. Further, the thickness of the above insulation film is commonly 50 nm-3 μm, but is preferably 100 nm-1 μm.

When an organic semiconductor is formed on the gate insulation layer, any appropriate surface treatment may be conducted on the gate insulation layer. A self organizing orientation film composed of silane coupling agents such as octadecyltrichlorosilane or octyltrichlorosilane, alkane phosphoric acid, alkane sulfonic acid, or alkane carboxylic acid is suitably employed.

### (Substrates)

Various materials are usable as support materials to constitute a substrate. For example, employed may be ceramic substrates such as glass, quartz, aluminum oxide, sapphire, silicon nitride, silicon carbide, and semiconductor substrates such as silicon, germanium, gallium arsine, as well as gallium nitrogen, paper, and unwoven cloth. However, in the present invention, it is preferable that the substrate is composed of resins. For example, plastic sheet film is usable. Examples of such plastic sheet film include those composed, for example, of polyethylene terephthalate (PET), polyethylene naphthalate (PEN), polyether sulfone (PES), polyether imide, polyether ether ketone, polyphenylene sulfide, polyacrylate, polyimide, polycarbonate (PC), cellulose triacetate (TAC), and cellulose acetate propionate (CAP). By employing such plastic film, it is possible to decrease weight compared to the case in which a glass substrate is employed. Further, it is possible to enhance portability and durability against impact.

Further, it is possible to arrange an element protective layer on the organic thin film transistor element of the present invention. The above inorganic oxides or inorganic nitrides, described as a protective layer, are cited as materials of the protective layer. It is preferable to form the protective layer employing the above atmospheric pressure plasma method, whereby the durability of the organic thin film transistor component is enhanced.

In the thin film transistor component of the present invention, when the support is a plastic film, it is preferable that at least one of a sublayer incorporating the compounds selected from inorganic oxides and inorganic nitrides, as well as a sublayer incorporating polymers.

Inorganic oxides incorporated in the sublayer include silicon oxide, aluminum oxide, tantalum oxide, and titanium oxide, while inorganic nitrides include silicon nitride and aluminum nitride.

Of these, preferred are silicon oxide, aluminum oxide, tantalum oxide, titanium oxide, and silicon nitride.

In the present invention, it is preferable that the sublayer incorporating the compounds selected from inorganic oxides and inorganic nitrides is formed via the above atmospheric pressure plasma method.

Listed as polymers employed in the sublayer incorporating polymers may be polyester resins, polycarbonate resins, cellulose resins, acrylic resins, polyurethane resins, polyethylene resins, polypropylene resins, polystyrene resins, phenoxy resins, norbornene resins, epoxy resins, vinyl based polymers such as vinyl chloride-vinyl acetate copolymers, vinyl chloride resins, vinyl acetate resins, vinyl acetate-vinyl alcohol copolymers, hydrolyzed vinyl chloride-vinyl acetate copolymers, vinyl chloride-vinylidene chloride copolymers, vinyl chloride-acrylonitrile copolymers, ethylene-vinyl alcohol copolymers, polyvinyl alcohol, chlorinated polyvinyl chloride, ethylene-vinyl chloride copolymers, ethylene-vinyl acetate copolymers, polyamide resins, rubber based resins such as ethylene-butadiene resins or butadiene-acrylonitrile, silicone resins, and fluorine based resins.

FIG. 2 is a view showing the representative component structure of the thin film transistor component in which the crystalline organic semiconductor thin film according to the present invention is employed.

FIGS. 2(a)-(f) are each a cross-section of some of the constitution examples of the thin film transistor in which the thin crystalline organic semiconductor film is employed which is produced via the production method of the crystalline organic semiconductor thin film according to the present invention. In FIG. 2, it is preferable that the organic semiconductor thin film results in a single (namely the polarization plane being the same) crystalline region so that the source electrode and the drain electrode are connected by using the thin film as a channel.

In FIG. 2(a), a field-effect transistor is formed in such a manner that source electrode 2 and drain electrode 3 are formed on support 6 employing metal foil; while employing the resulting support as a substrate, organic semiconductor layer 1, composed of the crystalline organic thin film of the present invention, is formed between the above electrodes employing the method of the present invention; and on the resulting film, insulation layer 5 is formed and further on the above, gate electrode 4 is formed. FIG. 2(b) shows another field-effect transistor formed in such a manner that organic semiconductor layer 1, which is formed between the electrodes in FIG. 2(a), is formed employing a coating method so that all of the electrodes and the support surface are covered. In FIG. 2(c), still another field-effect transistor is formed in such a manner that initially, organic semiconductor layer 1 is formed on support 6, employing the method of the present invention, and subsequently, source electrode 2, drain electrode 3, insulation layer 5, and gate electrode 4 are formed.

In FIG. 2(d), after forming gate electrode 4 on support 6 employing metal foil, insulation layer 5 is formed; on the resulting layer, source electrode 2 and drain electrode 3 are formed, and subsequently, organic semiconductor layer 1 prepared by employing the organic thin film transistor materials of the present invention, is formed between the above electrodes. The structures shown in FIGS. 2(e) and 2(f) may also be usable.

In the production method of the crystalline organic semiconductor thin film according to the present invention, some of the preferred embodiments will now be described.

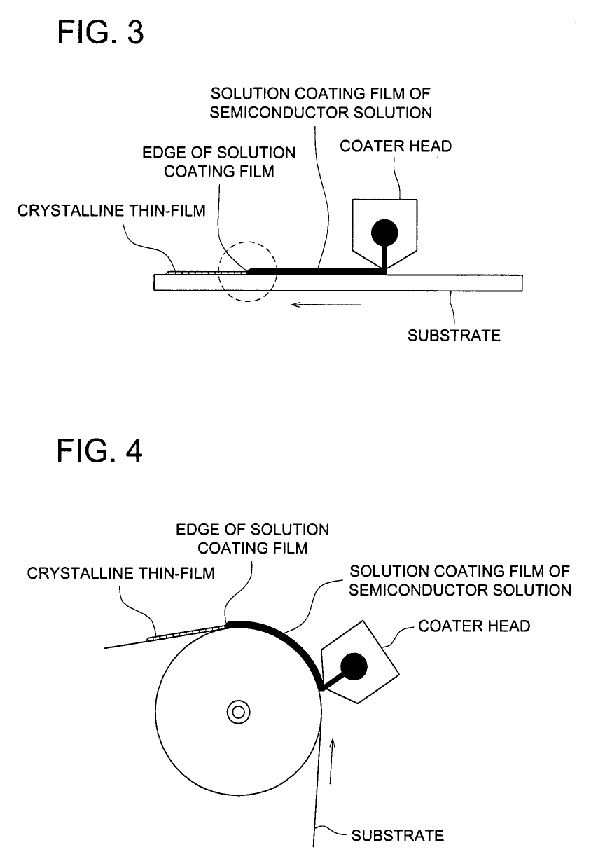

FIG. 3 shows an embodiment in which the crystalline organic semiconductor thin film according to the present invention is formed via die coater coating. In this case, coating is carried out employing a die coater while conveying the substrate. Conveyance may be relative, and the coater head may be conveyed. FIG. 3 shows that after applying an organic semiconductor solution onto the substrate, a crystalline thin film grows from the edge of the coating solution, and the crystal growth interface moves together with the edge of the solution coating film. In the area which is nearer the coater head than the edge of the solution coating film which shows the interface of the above crystal growth, the coating solution remains as applied. On the other hand, in the area further from the edge of the solution coating film, a single crystal region showing a uniform state of birefringence of a certain magnitude is formed and the crystal growth interface of the edge of the solution coating film is formed while moving along with coating. Further, above FIG. 1 is an enlarged view of the edge of the solution coating film.

FIG. 4 shows a coating embodiment employing a die coater in the same manner as above. However, an organic semiconductor thin film is formed on a plastic film such as polyethylene terephthalate employed as a substrate, employing a back-up roller. Other than the use of the back-up roller, the embodiment is basically same as in FIG. 3.

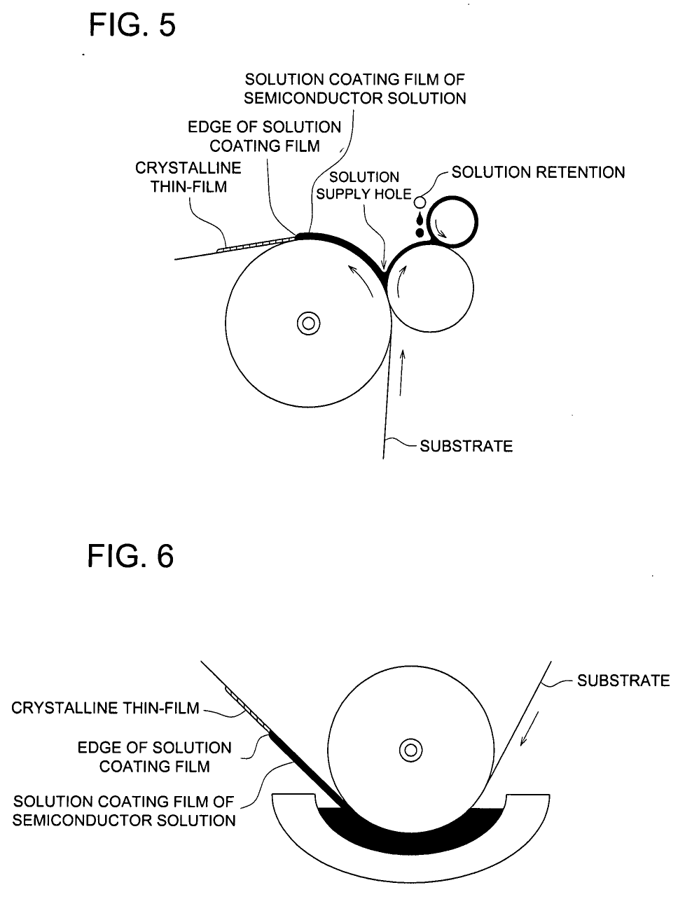

FIG. 5 shows an embodiment in which an organic semiconductor solution is applied onto a substrate employing roller coating. Coating is carried out as follows. The coating roller receives the organic semiconductor solution from a solution supplying hole, and the organic semiconductor solution is applied onto the substrate which is conveyed between the back-up roller and the coating roller via a solution retention formed between the back-up roller and the coating roller. The organic semiconductor solution coating, which is conveyed in the form of the back-up roller, is crystallized from the edge of the solution coating while forming the crystal growth interface.

Further, FIG. 6 shows formation of a crystalline organic semiconductor thin film of the present invention via dip coating. In this case, a coating film is formed while maintaining a constant volume of the organic semiconductor solution on the substrate in such a manner that the substrate comes into contact with the solution retention while the substrate is conveyed.

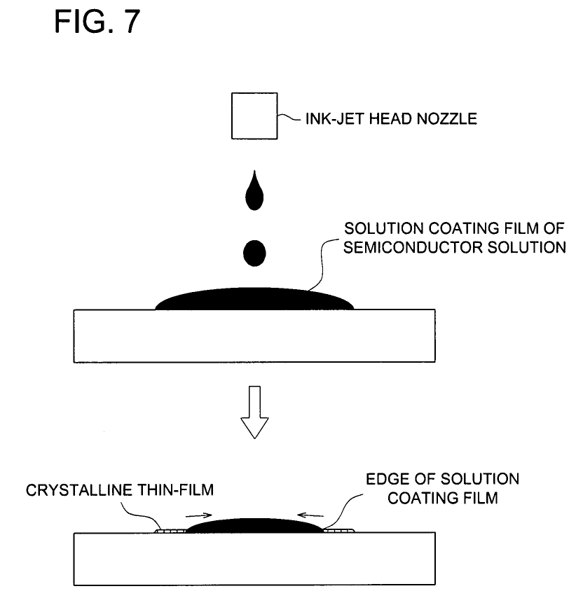

FIG. 7 is one example showing a practical embodiment employing an ink-jet method. It is possible to employ any of the appropriate ink-jet systems such as a piezo type, an electrostatic suction type, or a BUBBLE JET (registered trade name) type. A solution coating film is formed employing single type droplets or droplets of a plurality of types, and a crystalline organic semiconductor thin film is formed via crystal growth at the solution interface in the same manner as above. It is possible to carry out patterning via the ink-jet printing system, and it is also possible to carry out coating onto a relatively wide area as the above coating embodiments 1-4. When coating is carried out over a wide area, the coating film is the same as those formed via the above die or roller. In any of the above methods, semiconductor molecules are crystallized and grow in the π stack direction of the organic semiconductor molecules along with the backward migration of the wet film edge of the organic semiconductor material coating film.

As shown in the above preferred embodiment, according to the production method of the crystalline organic semiconductor thin film of the present invention, the interface of growth of the crystalline thin film is located at the edge of the coating solution film, namely nearly in the lateral direction of coating (though the orientation of crystals is not always completely the same as above), whereby the growth direction of the crystalline thin film is in right angles to this and the crystallization interface moves in the direction of the coater head.

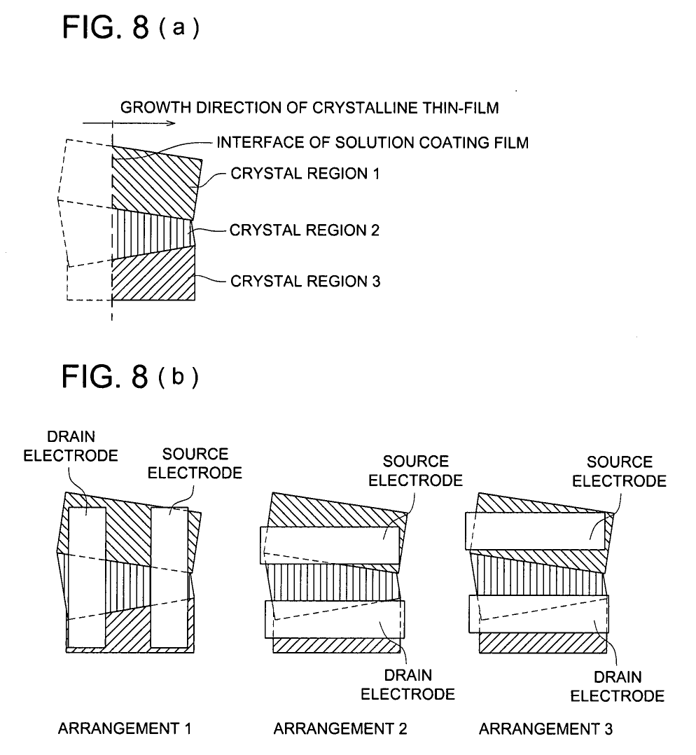

FIG. 8 shows the interface of the solution coating film and the growth direction of the crystalline thin film. A crystallized region having a plurality of single polarization planes is substantially formed. FIG. 8 shows the state in which, for example, three single crystal regions (crystal regions 1-3) are formed and also shows the growth direction of the crystalline thin film and the relationship of the interface of the solution coating film, namely the crystallized interface. As noted above, in the method of the present invention, the size of the single crystal region is about 25 μm²-about 25 mm².

In these single crystallized regions, which exhibit a state of uniform birefringence, the mobility of carriers is relatively high. Further, since in the orientation of formed crystals is nearly parallel to the growth direction of the crystalline thin film, it is preferable that the source electrode and the drain electrode are formed to include one region, as above, and are aligned in the growth direction of the crystalline thin film.

In the present invention, the state is preferred in which one crystal region exists between the source and drain electrodes, shown in FIG. 8(b).

Further, it is preferable that the source and drain electrodes are formed so that the growth direction of the crystalline thin film is more parallel to the direction between the source and drain electrodes. Accordingly, in FIG. 8(b), arrangement of the source electrode and the drain electrode is preferred in the order of Arrangement 1>Arrangement 2>Arrangement 3.

### EXAMPLES

The present invention will now be specifically described with reference to examples; however, the present invention is not limited thereto.

### Example 1

An n-type wafer at a specific resistance of 0.02 Ω·cm, on which surface a 200 nm thermally oxidized film was formed, was employed as a substrate. The surface energy of the thermally oxidized film was 6.0×10⁻² N/m, and the actual measurement value of the contact angle was 46°.

A toluene solution, in which the following organic semiconductor material (OSC2-1) (0.05% by weight) was dissolved, was dripped onto the above thermally oxidized film at a substrate temperature of 60° C. while being stationary, whereby a cast film was formed. Immediately after the dripping, an approximately 200 μm solution coating film was formed on the surface of the thermally oxidized film, and the edge of the solution coating film was also allowed to remain stationary. During observation via a microscope, it was noted that about 5 seconds after the dripping, the solid-liquid interface at the edge of the solution coating film moved backward due to evaporation of toluene as a solvent and simultaneously, a crystalline thin film was formed at the interface. At that time, the migration rate of the solid-liquid interface was 230 μm/second. Further, at the edge, minute crystals via segregation were noted. It was found that a crystalline thin film grew from the above crystals. The polarization image of the cast film was viewed employing a polarization microscope, resulting in formation of a single crystal region, namely a region having a state exhibiting uniform birefringence of 500 μm in four directions. Further, the thickness of the resulting cast film was 80 nm.

Further, gold was deposited onto the surface of the resulting film, employing a mask, whereby a source electrode and a drain electrode were formed.

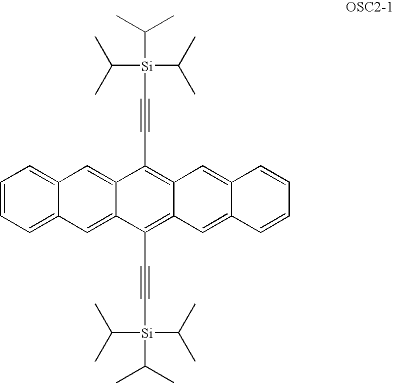

As described above, prepared was a thin film transistor at channel length L of 30 μm and a channel width of 1 mm. The resulting transistor desirably worked as a p channel enhancement type FET. Carrier mobility in the saturated region was determined based on the I-V characteristics of the prepared transistor, resulting in 0.7 cm²/Vs.

### Example 2

A toluene solution, in which an organic semiconductor material (OSC2-1) (0.05% by weight) was dissolved, was dripped onto the Si wafer having thereon a thermally oxidized film, which was the same as in Example 1, and the resulting about 200 μm thick solution coating film was allowed to remain stationary at room temperature. Subsequently, three minutes after the above operation, the Si wafer was declined 45°, the solution coating film flowed on the surface of the substrate depending on the inclination and the solution coating film flowed down at a rate of 300 μm/second, whereby a cast film was formed. Immediately after the dripping, an approximately 200 μm thick solution coating film was formed on the surface of the thermally oxidized film, and the edge of the solution coating film was also allowed to remain stationary. During observation via a microscope, it was noted that about 5 seconds after the dripping, the edge of the solution coating film moved backward due to evaporation of toluene as a solvent and simultaneously, a crystalline thin film formed at the interface. At that time, the migration rate of the edge was 230 μm/second. Further, in the edge, minute crystals via segregation were noted. It was found that a thin crystalline film grew from the above crystals. The polarization image of the cast film was viewed employing a polarization microscope, resulting in formation of a single crystal region, namely a region of a state exhibiting uniform birefringence 500 μm in four directions. Further, the thickness of the resulting cast film was 80 nm. In the flow trace, a thin crystalline film formed in the surface of the solution coating film was recognized. The polarization image of the cast film was investigated employing a polarization microscope, resulting in formation of a single crystal region at a size of 50 μm in four directions. Further, the thickness of the resulting cast film was 60 nm.

Further gold was deposited onto the surface of the resulting film, employing a mask, whereby a source electrode and a drain electrode were formed.

The transistor prepared in the same manner as Example 1 desirably worked as a p channel enhancement type FET. The carrier mobility, determined in the same manner as Example 1, was 0.5 cm²/Vs.

### Comparative Example

A toluene solution, in which an organic semiconductor material (OSC2-1) (0.05% by weight) was dissolved, was dripped onto the Si wafer having thereon a thermally oxidized film, which was the same as in Example 1, and a cast film was formed at a substrate temperature of 60° C., under a warm air flow onto the solution coating film, employing a drier. The edge, which was noted in Examples 1 and 2, was not apparent, and the entire solution coating film was almost simultaneously dried. The polarization image of the cast film was viewed via a polarization microscope, resulting in formation of a single crystal region, namely a region at a state of uniform birefringence 500 μm in four directions. Further, the thickness of the resulting cast film was 80 nm. In the flow trace, a crystalline thin film formed on the surface of the solution coating film was noted. The polarization image of the cast film was viewed via a polarization microscope, resulting in no recognition of a single crystal region, namely a region at state of uniform birefringence. The thickness of the resulting cast film was 80 nm.

Further gold was deposited onto the surface of the resulting film, employing a mask, whereby a source electrode and a drain electrode were formed.

As described above, prepared was a thin film transistor at channel length L of 30 μm and a channel width of 1 mm. The resulting transistor desirably worked as a p channel enhancement type FET. Carrier mobility in the saturated region was determined based on the I-V characteristics of the prepared transistor, resulting in 0.0002 cm²/Vs.

It was found that based on the method of the present invention, a thin film transistor exhibiting high carrier mobility was prepared.

What is claimed is:

1. A method of producing a crystalline organic semiconductor thin film comprising the steps of:
(a) coating a solution of an organic semiconductor material in a solvent onto a substrate to form a liquid coating film; and
(b) crystallizing the organic semiconductor material in the liquid coating film at an edge of the liquid coating film on the substrate so as to grow a crystalline of the organic semiconductor material.

2. The method of producing a crystalline organic semiconductor thin film of claim 1,
wherein the crystalline organic semiconductor thin film grows by moving a solid-liquid interface formed by a crystallized portion and a liquid portion of the coating film.

3. The method of producing a crystalline organic semiconductor thin film of claim 1,
wherein the crystallization step (b) is conducted by evaporation of the solvent in the coating film.

4. The method of producing a crystalline organic semiconductor thin film of claim 2,
wherein a moving rate of the solid-liquid interface is controlled so as to be 20 μm/sec or more in a direction parallel to a coating direction.

5. The method of producing a crystalline organic semiconductor thin film of claim 1,
wherein the liquid coating film of the solution of the organic semiconductor material has a thickness of 500 μm or less.

6. The method of producing a crystalline organic semiconductor thin film of claim 1,
wherein the organic semiconductor material is a condensed polycyclic aromatic compound.

7. The method of producing a crystalline organic semiconductor thin film of claim 6,
wherein the condensed polycyclic aromatic compound is represented by Formula (OSC1): 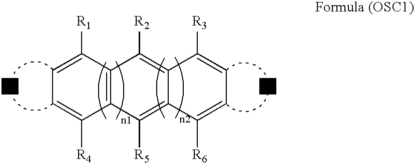
wherein R₁-R₆ each represent a hydrogen atom or a substituent; Z₁ and Z₂ each represent a group of atoms to form a substituted on unsubstituted aromatic hydrocarbon ring, or a substituted or unsubstituted aromatic heterocyclic ring; and n1 and n2 each represent an integer of 0-3.

8. The method of producing a crystalline organic semiconductor thin film of claim 7,
wherein the condensed polycyclic aromatic compound is represented by Formula (OSC2): 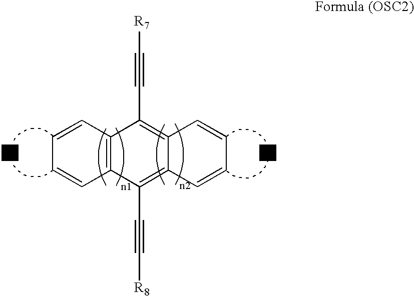
wherein R₇ and R₈ each represent a hydrogen atom or a substituent; Z₁ and Z₂ each represent a group of atoms to form a substituted or unsubstituted aromatic hydrocarbon ring, or a substituted or unsubstituted aromatic heterocyclic ring, and n1 and n2 each represent an integer of 0-3.

9. The method of producing a crystalline organic semiconductor thin film of claim 8,
wherein R₇ and R₈ in Formula (OSC2) each are represented by Formula (SG1): 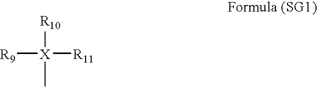
wherein R₉-R₁₁ each represent a substituent; and X represents Si, Ge, or Sn.

10. An organic semiconductor thin film produced by the method of claim 1.

11. An electronic device comprising the organic semiconductor thin film of claim 10.

12. A thin film transistor comprising the organic semiconductor thin film of claim 10.
